(19) United States
(12) Patent Application Publication
(10) Pub. No.: US 2010/0013076 A1
(43) Pub. Date: Jan. 21, 2010

(54) SEMICONDUCTOR DEVICE PACKAGE AND METHOD OF FABRICATING THE SAME

(75) Inventors: Chul-Yong Jang, Yongin-si (KR); Pyoung-Wan Kim, Suwon-si (KR); Teak-Hoon Lee, Hwaseong-si (KR)

Correspondence Address: STANZIONE & KIM, LLP, 919 18TH STREET, N.W., SUITE 440, WASHINGTON, DC, 20006, US

(73) Assignee: Samsung Electronics., Co., Ltd., Suwon-si (KR)

(21) Appl. No.: 12/505,606

(22) Filed: Jul. 20, 2009

(30) Foreign Application Priority Data
Jul. 21, 2008 (KR) 2008-70719

(51) Int. Cl. H01L 23/16; H01L 23/52

(52) U.S. Cl. 257/687; 257/693; 257/690; 257/E23.135; 257/E23.01; 257/E23.141

(57) ABSTRACT

A semiconductor device package includes a semiconductor chip having a top surface on which a conductive pad is disposed, a bottom surface opposite to the top surface, and a side surface connecting the top and bottom surfaces to each other; a first insulating layer covering the top surface of the semiconductor chip and laterally extending to the outside of the semiconductor chip; a fillet member covering a boundary where the side surface of the semiconductor chip and the first insulating layer meet each other; and a molding layer covering the bottom surface of the semiconductor chip, the fillet member, and the first insulating layer.

### CROSS-REFERENCE TO RELATED APPLICATIONS

This U.S non-provisional patent application claims priority under 35 U.S.C §119 to Korean Patent Application No. 10-2008-0070719, filed on Jul. 21, 2008, in the Korean Intellectual Property Office (KIPO), the entirety of which is incorporated herein by reference.

### BACKGROUND

1. Field of the Invention

Embodiments of the present general inventive concept relates to semiconductor device package and method of fabricating the same. More specifically, the embodiments of the present general inventive concept are directed to a fan-out semiconductor device package and a method of fabricating the same.

2. Description of the Related Art

As the integration density of semiconductor devices increases, semiconductor chips each being cut into individual chip units continue to shrink in size. For this reason, semiconductor device packages also continue to shrink in size. For example, there are chip-scale packages (CSP) manufactured at a semiconductor chip scale to readily reduce their sizes.

As semiconductor chips continue to shrink in size, there may be restrictions in locating an external connection terminal electrically connected to a fine-pitch chip pad disposed at a semiconductor chip in a semiconductor device package. To overcome these restrictions, there can be provided a “fan-out” semiconductor device package where an external connection terminal is attached to the exterior of a semiconductor chip.

### SUMMARY

Embodiments of the present general inventive concept provide a semiconductor device package. In an exemplary embodiment, the semiconductor device package may include: a semiconductor chip having a top surface on which a conductive pad is disposed, a bottom surface opposite to the top surface, and a side surface connecting the top and bottom surfaces to each other; a first insulating layer covering the top surface of the semiconductor chip and laterally extending to the outside of the semiconductor chip; a fillet member covering a boundary where the side surface of the semiconductor chip and the first insulating layer meet each other; and a molding layer covering the bottom surface of the semiconductor chip, the fillet member, and the first insulating layer.

Embodiments of the present general inventive concept may also provide a method of fabricating a semiconductor device package. In another exemplary embodiment, the method may include: preparing a carrier to which an adhesive layer having both adhesive surfaces is attached; preparing a semiconductor chip having a top surface on which a conductive pad is disposed, a bottom surface opposite to the top surface, and a side surface connecting the top and bottom surfaces to each other; attaching the top surface of the semiconductor chip to the adhesive layer; forming a fillet member to cover a boundary where the side surface of the semiconductor chip and the adhesive layer meet each other; and forming a molding layer to cover the bottom surface of the semiconductor chip, the fillet member, and the adhesive layer.

Embodiments of the present general inventive concept may also provide a method of fabricating a semiconductor device package, the method including attaching a top surface of a semiconductor chip to a double sided adhesive layer adhered on a carrier, forming a fillet member to cover a boundary where at least one side surface of the semiconductor chip and the adhesive layer intersect each other, and forming a molding layer to cover the bottom surface of the semiconductor chip, the fillet member, and the adhesive layer.

Additional features and utilities of the present general inventive concept will be set forth in part in the description which follows and, in part, will be obvious from the description, or may be learned by practice of the general inventive concept.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIGS. 1A and 1B are a cross-sectional view and a perspective view of a semiconductor device package according to an embodiment of the present general inventive concept, respectively.

FIGS. 2 through 7 are cross-sectional views illustrating a method of fabricating a semiconductor device package according to an embodiment of the present general inventive concept.

FIGS. 8A and 8B are a cross-sectional view and a perspective view of a semiconductor device package according to an alternative embodiment of the present general inventive concept, respectively.

FIG. 9 is a block diagram illustrating a system of an electronic equipment according to the embodiments of the present general inventive concept.

### DETAILED DESCRIPTION OF THE EMBODIMENTS

The embodiments of the present general inventive concept will now be described more fully hereinafter with reference to the accompanying drawings, in which preferred embodiments of the general inventive concept are shown. This general inventive concept, however, may be embodied in many different forms and should not be construed as limited to the embodiments set forth herein. Rather, these embodiments are provided so that this disclosure will be thorough and complete, and will fully convey the scope of the general inventive concept to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

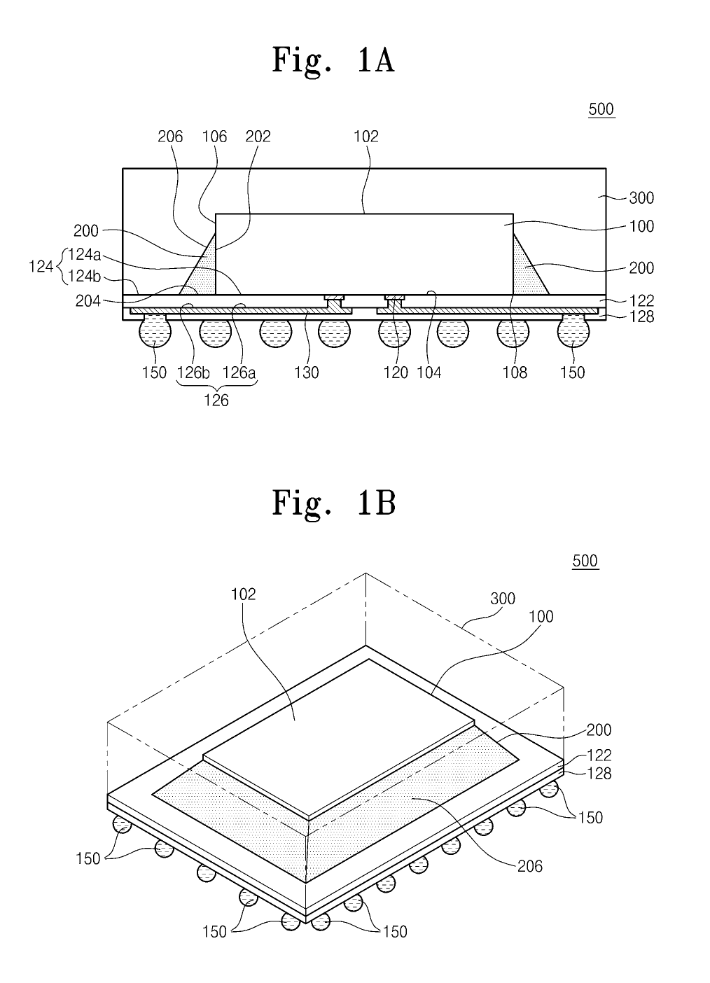

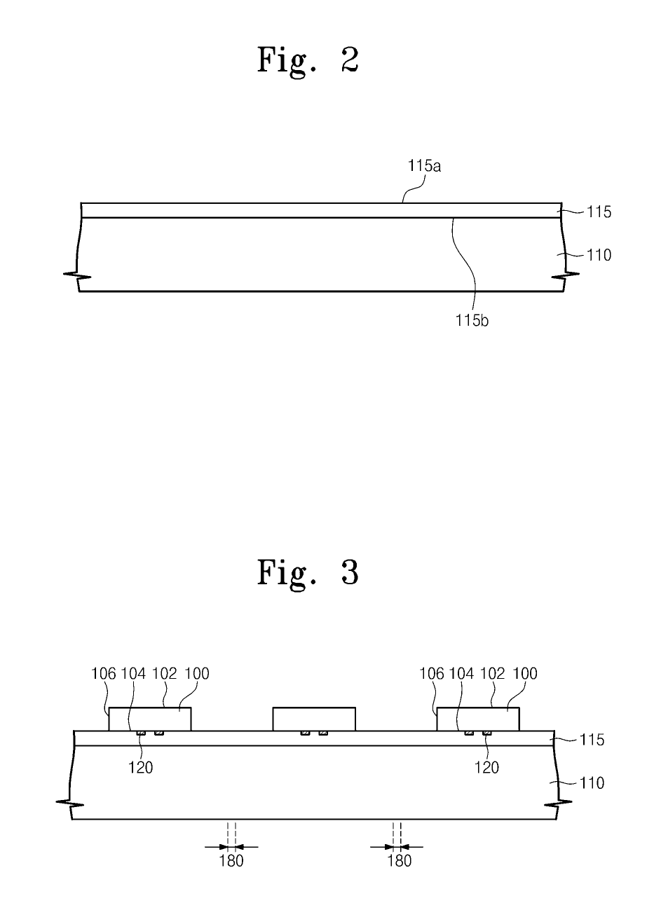

Referring to FIGS. 1A and 1B, there are a cross-sectional view and a perspective view of a semiconductor device package 500 according to an embodiment of the present general inventive concept. The semiconductor device package 500 includes a semiconductor chip 100, a rerouting pattern 130 extending to the outside of the semiconductor chip 100, and a fillet member 200. The semiconductor device package 500 may be, for example, a fan-out package.

The semiconductor chip 100 may have a top surface 104, a bottom surface 102 opposite to the top surface 104, and a side surface 106 connecting the top and bottom surfaces 104 and 102 to each other. An integrated circuit (not shown) is formed at the semiconductor chip 100. A conductive pad 120 is disposed on the top surface 104 of the semiconductor chip 100, as an active surface. The conductive pad 120 is electrically connected to the integrated circuit. The conductive pad 120 may comprise a plurality of conductive pads disposed at the center of the top surface 104. The disposition of the conductive pad 120 is not limited to the above. The conductive pad 120 may be made of a conductive material such as aluminum (Al), copper (Cu) or an alloy thereof.

A first insulating layer 122 may be provided on the top surface 104 of the semiconductor chip 100. The first insulating layer 122 may cover the top surface 104 of the semiconductor chip 100 while exposing the conductive pad 120 and may extend to the outside of the semiconductor chip 100. The first insulating layer 122 may include a thermosetting material. The first insulating layer 122 may include, for example, a polyimide-based material. The first insulating layer 122 may have a first surface 124a which is in contact with the top surface 104 of the semiconductor chip 100 and a second surface 126a opposite to the first surface 124a. The first insulating layer 122 may have a first extension surface 124b extending from the first surface 124a and a second extension surface 126b opposite to the first extending surface 124b. The second extension surface 126b may extend from the second surface 126a. The first surface 124a and the first extension surface 124b may constitute the top surface 124 of the first insulating layer 122, and the second surface 126a and the second extension surface 126b may constitute the bottom surface 126 of the first insulating layer 122.

A rerouting pattern 130 may be disposed on the first insulating layer 122. The rerouting pattern 130 may be electrically connected to the conductive pad 120 and laterally extend to the outside of the semiconductor chip 100 along the second surface 126a and the second extension surface 126b of the first insulating layer 122. The rerouting pattern 130 may be made of a conductive material such as one of metals having a relatively superior electroconductivity and an alloy thereof. The metals can be, for example, copper (Cu), nickel (Ni), platinum (Pt), silver (Ag), and gold (Au). A second insulating layer 128 including an opening may be provided to cover the rerouting pattern 130 while exposing a portion of the extending rerouting pattern 130. The opening may be disposed at the outside of the semiconductor chip 100. An external connection member 150 is provided on a portion of the extending rerouting pattern 130. The external connection member 150 can electrically connect the rerouting pattern 130 to an external circuit. The external connection member 150 may be, for example, a solder ball.

The fillet member 200 may cover a boundary 108 where the side surface 106 of the semiconductor chip 100 and the top surface 124 of the first insulating layer 122 meet. The fillet member 200 may include a thermosetting material. The fillet member 200 may include, for example, a polyimide-based material. The fillet member 200 may adopt the same or similar material as or to an insulating material of which the first insulating layer 122 is made. Therefore, the fillet member 200 and the first insulating layer 122 may be reliably connected to each other. The fillet member 200 may be disposed to expose a portion of the side surface 106 of the semiconductor chip 100 and a portion of the first extension surface 124b of the first insulating layer 122. The fillet member 200 may have, for example, a ring shape.

The fillet member 200 may have a third surface 202 that is in contact with the side surface 106 of the semiconductor chip 100, a fourth surface 204 that is in contact with the first extension surface 124b of the first insulating layer 122, and a fifth surface 206 connecting the third and fourth surfaces 202 and 204 to each other. The fillet member 200 may be disposed not to expose the side surface 106 of the semiconductor chip 100. The fillet member 200 may be disposed not to expose the first extension surface 124b of the first insulating layer 122.

If the fillet member 200 is not disposed and the semiconductor chip 100, a molding layer 300, and the first insulating layer 122 are made of different materials, a stripping phenomenon may be increased. According to an embodiment, a stripping phenomenon may be suppressed. This is because the fillet member 200 and the first insulating layer 122 are more reliably connected at the boundary 108 where the semiconductor chip 100, the first insulating layer 122 and the fillet member 200 meet than at the boundary where the semiconductor chip 100, the molding layer 300 and the first insulating layer 122 meet each other. That is, the fillet member 200 and the first insulating layer 122 are made of the same material or different materials to suppress a stripping phenomenon resulting from a difference in expansion coefficient of the semiconductor chip 100, the molding layer 300, and the first insulating layer 122. Accordingly, reliability of a semiconductor device including a semiconductor device package according to embodiments of the present general inventive concept may be enhanced in a reliability test (e.g., heat-resistance test and bending test) of a semiconductor device.

The molding layer 300 may be disposed to cover the bottom surface 102 of the semiconductor chip 100, the fifth surface 206 of the fillet member 200, and a portion of the first extension surface 124b of the first insulating layer 122. The molding layer 300 may be made of a molding resin such as epoxy molding compound (EMC).

FIGS. 2 through 7 are cross-sectional views illustrating a method of fabricating a semiconductor device package according to an embodiment of the present general inventive concept.

Referring to FIG. 2, a carrier 110 having a top surface and a bottom surface opposite to the top surface is prepared. The carrier 110 may have, for example, a plate or disc shape and may be reused.

A second surface 115b of an adhesive layer 115 is attached to a carrier 110. The adhesive layer 115 includes a first surface 115a opposite to the second surface 115b. The adhesive layer 115 is an insulating layer, and each of the first and second surfaces 115a and 115b may have an adhesive property.

Referring to FIG. 3, individually separated semiconductor chips 100 are prepared by cutting a semiconductor wafer at locations where a plurality of semiconductor chips 100 are formed. Each of the semiconductor chips 100 has a top surface 104, a bottom surface 102 opposite to the top surface 104, and a side surface 106 connecting the top and bottom surfaces 104 and 102 to each other. An integrated circuit (not shown) is formed at the semiconductor chip 100. A conductive pad 120 is formed on the top surface 104 of the semiconductor chip 100 as an active surface, being electrically connected to the integrated circuit. The conductive pad 120 may include, for example, a plurality of conductive pads arranged around the center of the top surface 104. However, the disposition of the conductive pad 120 is not limited to the above. The conductive pad 120 may be formed of a conductive material such as aluminum (Al), copper (Cu) or an alloy thereof.

While adjusting a distance between the semiconductor chips 100, the semiconductor chip 100 is attached to the first surface 115a of the adhesive layer 115. The distance between the semiconductor chips 100 may be adjusted such that an external connection terminal, e.g., a solder ball (150 of FIG. 1) may be disposed at the outside of the semiconductor chip 100. A singulation region 180 may be defined at a predetermined region between the semiconductor chips 100. The singulation region 180 may be a separation region to individually separate semiconductor chips 100 molded in a subsequent process. The semiconductor chip 100 may be divided by the singulation region 180.

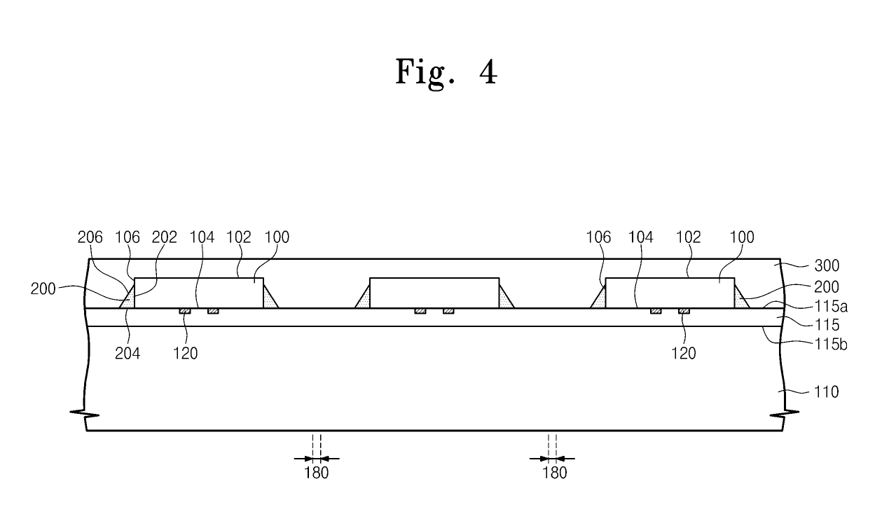

Referring to FIG. 4, a fillet member 200 may be formed by coating a boundary, where the side surface 106 of the semiconductor chip 100 and the first surface 115a of the adhesive layer 115 meet each other, with an insulating material and hardening the coated insulating material. The fillet member 200 may include a thermosetting material. The fillet member 200 may include, for example, a polyimide-based material. The fillet member 200 may cover the boundary where the side surface 106 of the semiconductor chip 100 and the first surface 115a of the adhesive layer 115 meet each other. The fillet member 200 may include a third surface 202 that is in contact with the side surface 106 of the semiconductor chip 100, a fourth surface 204 attached to the first surface 115a of the adhesive layer 115 outside the semiconductor chip 100, and a fifth surface 206 connecting the third and fourth surfaces 202 and 204 to each other. The fifth surface 206 of the fillet member 106 is exposed. A portion of the side surface 106 of the semiconductor chip 100 and a portion of the adhesive layer 115 may be exposed. The fillet member 200 may have, for example, a ring shape. The fillet member 200 may be formed not to expos the side surface 106 of the semiconductor chip 100. The fillet member 100 may be formed not to expose the first surface 115a of the adhesive layer 115 between the semiconductor chips 100.

A molding layer 300 may be formed to cover the bottom surface 102 of the semiconductor chip 100, the fifth surface 206 of the fillet member 200, and the exposed adhesive layer 115 between the semiconductor chips 100. The molding layer 300 may be formed by pressurizing and injecting a molding material on the bottom surface 102 of the semiconductor chip 100, the fifth surface 206 of the fillet member 200, and the exposed adhesive layer 115 and hardening the injected molding material. The molding layer 300 may be formed of a molding resin such as, for example, epoxy molding compound (EMC).

A pressure applied to the semiconductor chip 100 during injection of the molding material may be relieved by the fillet member 200 to make the semiconductor chip 100 move less than the semiconductor chip 100 attached only to the adhesive layer 115 without a fillet member. Moreover, the fillet member 200 may prevent the molding material from penetrating between the semiconductor chip 100 and the adhesive layer 115 while hardening the molding material. That is, the fillet member 200 may serve to prevent the top surface 104 of the semiconductor chip 100 from being contaminated by movement of the semiconductor chip 100 and penetration of the molding material. Accordingly, in a subsequent process of a rerouting pattern and a subsequent process of providing an external connection terminal, misalignment between the rerouting pattern and the external connection terminal and poor connection between a chip pad and the rerouting pattern may be suppressed to enhance performance of a semiconductor device package.

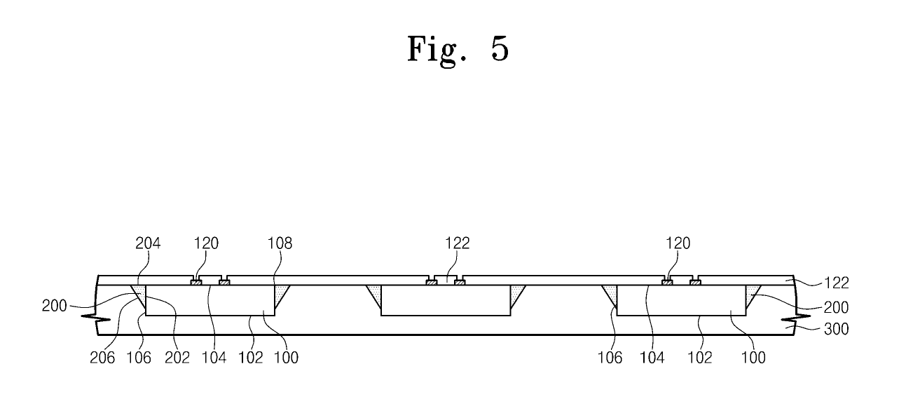

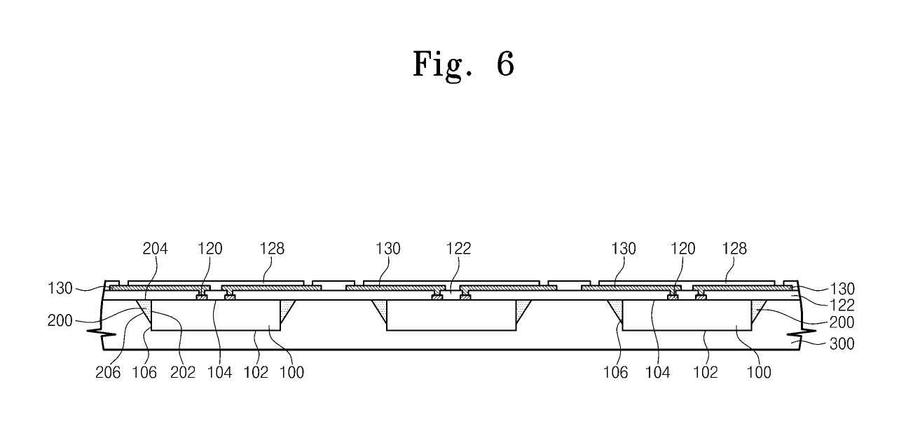

Referring to FIG. 5, an adhesive layer (115 of FIG. 4) is removed to expose the top surface 104 of the semiconductor chip 100, the fourth surface 204 of the fillet member 200, and the molding layer 300 between the semiconductor chips 100. A carrier (110 of FIG. 4) may be recovered to be reused.

A first insulating layer 122 including a first opening may be formed to cover the top surface 104 of the semiconductor chip 100 while exposing the conductive pad 120. The first insulating layer 122 may cover the fourth surface 204 of the fillet member 200 and the exposed molding layer 300 between the semiconductor chips 100. The first insulating layer 122 may be formed of the same or similar material as or to the insulating material constituting the fillet member 200. Thus, the fillet member 200 and the first insulating layer 122 may be reliably connected to each other.

If the fillet member 200 is not formed and the semiconductor chip 100, a molding layer 300, and the first insulating layer 122 are made of different materials, a stripping phenomenon may be increased. According to embodiments of the present general inventive concept, a stripping phenomenon may be suppressed. This is due to the fillet member 200 and the first insulating layer 122 being more reliably connected at the boundary 108 where the semiconductor chip 100, the first insulating layer 122 and the fillet member 200 meet than at the boundary where the semiconductor chip 100, the molding layer 300 and the first insulating layer 122 meet each other.

Referring to FIG. 6, the first opening of the first insulating layer 122 may be filled to form a rerouting pattern 130, which is electrically connected to the exposed conductive pad 120 and laterally extends along a top surface of the first insulating layer 122. The rerouting pattern 130 may be formed of a conductive material such as one of metals having a relatively superior electroconductivity and an alloy thereof. The metals are, for example, copper (Cu), nickel (Ni), platinum (Pt), silver (Ag), and gold (Au).

A second insulating layer 128 including a second opening may be formed to cover a portion of the laterally extending rerouting pattern 130.

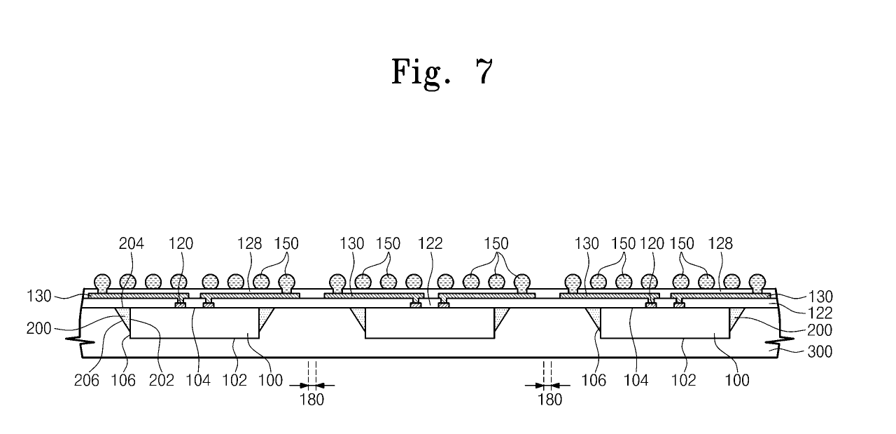

Referring to FIG. 7, an external connection member 150, e.g., a solder ball may be provided on the exposed rerouting pattern 130. The external connection member 150 can electrically connect the rerouting pattern 130 to an external circuit. The molding layer 300, the first insulating layer 122, and the second insulating layer 128 of a singulation region 180 may be cut to achieve a semiconductor device package 500 illustrated in FIG. 1A.

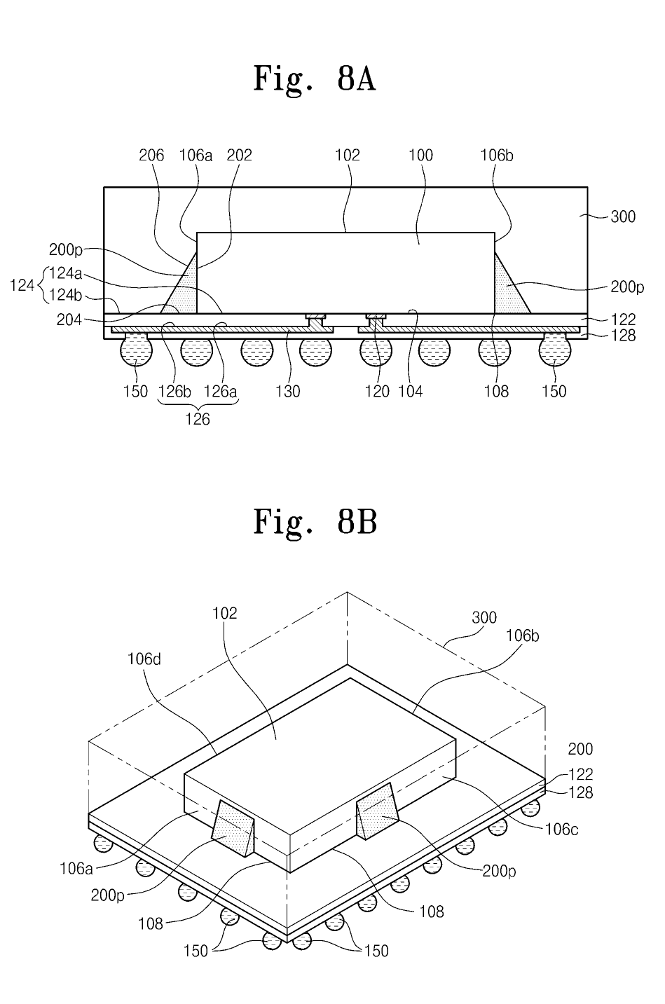

FIGS. 8A and 8B are a cross-sectional view and a perspective view of a semiconductor device package according to an alternative embodiment of the present general inventive concept, respectively. The semiconductor package according to the alternative embodiment may be similar to that according to the foregoing embodiment. Therefore, duplicate explanations thereof may be described briefly or omitted.

Referring to FIGS. 8A and 8B, a side surface of a semiconductor chip 100 may include first and second side surfaces 106a and 106b facing each other and third and fourth side surfaces 106c and 106d facing each other. The first and second side surfaces 106a and 106b are connected to the third and fourth side surfaces 106c and 106d. A fillet member 200p may be disposed on the first to fourth side surfaces 106a, 106b, 106c, and 106d to cover portions of their boundaries 108, respectively. The fillet member 200p may be disposed on at least one of the first to fourth side surfaces 106a, 106b, 106c, and 106d. The fillet member 200p may comprise a plurality of fillet members spaced apart from each other. Forming the plurality of fillet members may include coating boundaries 108 with thermosetting materials one by one and hardening the thermosetting materials.

In another alternative embodiment, the fillet member 200p may include a plurality of fillet members spaced apart from each other along the boundaries 108.

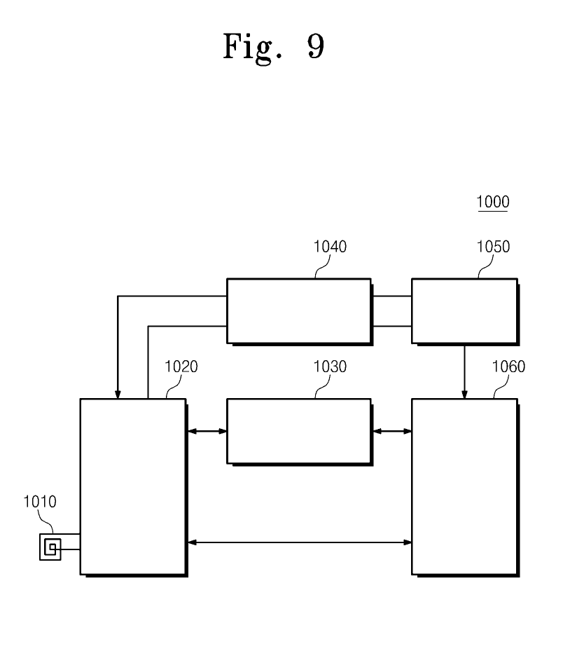

FIG. 9 is a block diagram illustrating an electronic equipment system including a semiconductor device according to embodiments of the present general inventive concept. The electronic system may include a mobile communication terminal 1000 including, for example, a radio frequency communication chip (RF chip) 1020, a smart card 1030, a switching circuit 1040, a battery 1050, and a controller 1060. The mobile communication terminal 1000 may include a semiconductor device according to embodiments described above. That is, the mobile communication terminal 1000 may include a semiconductor device having improved chemical strength and reliability.

The semiconductor device according to the embodiments of the present general inventive concept may be manufactured with a memory chip or a logic chip. The RF chip 1020 may include, for example, a process and a memory chip. The smart card 1030 may include a memory chip, and the controller 1060 may include a logic chip.

The RF chip 1020 transmits/receives wireless signals to/from an external RFID reader (not shown) through an antenna 1010. The RF chip 1020 transmits a signal received from the smart card 1030 or the controller 1060 to the RFID reader and transmits a signal received from the RFID reader through the antenna 1010 to the smart card 1030 or the controller 1060. The smart card 1030 communicates with the RF chip 1020 and the controller 1060. The battery 1050 supplies power that the mobile communication terminal 1000 needs. The controller 1060 controls general operations of the mobile communication terminal 1000.

The electronic equipment including a semiconductor device package 500 according to the embodiments of the present general inventive concept may include, for example, not only a mobile communication terminal 1000 but also various mobile devices such as personal digital assistants (PDA), MP3 players, movie players, portable game machines, etc., desktop computers, mainframe computers, global positioning systems (GPS), PC cards, notebook computers, camcorders, and digital cameras.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A semiconductor device package comprising:
a semiconductor chip having a top surface on which a conductive pad is disposed, a bottom surface opposite to the top surface, and a side surface connecting the top and bottom surfaces to each other;
a first insulating layer covering the top surface of the semiconductor chip and laterally extending to the outside of the semiconductor chip;
a fillet member covering a boundary where the side surface of the semiconductor chip and the first insulating layer intersect each other; and
a molding layer covering the bottom surface of the semiconductor chip, the fillet member, and the first insulating layer.

2. The semiconductor device package as set forth in claim 1, wherein the fillet member include the same material as the first insulating layer.

3. The semiconductor device package as set forth in claim 1, wherein the first insulating layer has a first surface which is in contact with the top surface of the semiconductor chip, a second surface which is opposite to the first surface, a first extension surface which extends to the first surface, and a second extension surface which extends from the second surface and is opposite to the first extension surface.

4. The semiconductor device package as set forth in claim 3, wherein the fillet member has a third surface which covers the boundary and is closely adjacent to the side surface of the semiconductor chip and a fourth surface which is closely adjacent to the first extension surface of the first insulating layer.

5. The semiconductor device package as set forth in claim 4, wherein the fillet member covers up the side surface of the semiconductor chip.

6. The semiconductor device package as set forth in claim 4, wherein the fillet member covers up the extension surface of the first insulating layer.

7. The semiconductor device package as set forth in claim 1, wherein the side surface of the semiconductor chip includes a first side surface and a second side surface which face each other and a third side surface and a fourth side surface which are connected to the first and second side surfaces and face each other.

8. The semiconductor device package as set forth in claim 7, wherein the fillet member is disposed at least one of the first to fourth side surfaces.

9. The semiconductor device package as set forth in claim 3, wherein the first insulating layer includes a first opening exposing the conductive pad.

10. The semiconductor device package as set forth in claim 9, further comprising:
a rerouting pattern electrically connected to the exposed conductive pad and extending to the outside of the semiconductor chip along the second surface and the second extension surface of the first insulating layer;
a second insulating layer having a second opening covering the rerouting pattern while exposing a portion of the extending rerouting pattern; and
an external connection terminal provided on the exposed rerouting pattern and electrically connected to the rerouting pattern.

11. The semiconductor device package as set forth in claim 10, wherein the second opening is formed outside the semiconductor chip.

12-25. (canceled)
